(19) United States
(12) Patent Application Publication
(10) Pub. No.: US 2011/0247681 A1
(43) Pub. Date: Oct. 13, 2011

(54) METHOD FOR MANUFACTURING MULTILAYER FILMS AND SOLAR PANEL BACKSHEETS FORMED THEREOF

(75) Inventor: Qiuju Wu, Shanghai (CN)

(73) Assignee: E. I. DU PONT DE NEMOURS AND COMPANY, Wilmington (DE)

(21) Appl. No.: 12/900,529

(22) Filed: Oct. 8, 2010

(30) Foreign Application Priority Data
Oct. 10, 2009 (CN) 200910205228.3

(51) Int. Cl. H01L 31/048; B32B 38/18; B32B 27/08

(52) U.S. Cl. 136/251; 428/421; 428/354; 156/163

(57) ABSTRACT

Disclosed herein is a method for manufacturing of multilayer laminated films, comprising: (a) providing a fluoropolymer film; (b) providing a stretched polyester film; (c) providing an ethylene polymer; and (d) forming a multilayer laminated film comprising fluoropolymer/ethylene copolymer/stretched polyester by an extrusion coating method at a temperature of 270° C. or higher, wherein the ethylene copolymer of step (c) is a copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight, preferably accounting for 65-85% by weight, and ideally accounting for 70-80% by weight. A multilayer laminated film manufactured by means of this method and the solar panel comprising this multilayer laminated film are also disclosed herein.

### FIELD OF THE INVENTION

The present invention relates to a lamination method used in the manufacture of multilayer films and the multilayer laminated films formed thereof. The present invention also relates to solar cells which employ such multilayer laminated films as a back sheet.

### BACKGROUND OF THE INVENTION

Governments are placing increasing emphasis on energy conservation and emission reduction. As a result, the search for new energy sources to replace fossil fuels is taking on increasing urgency. Solar energy is a clean, pollution-free and inexhaustible energy source. At present, solar energy is harnessed primarily by its conversion into electricity by solar panels, which is then used to power electric water heaters, electric vehicles, and satellite components, for example.

A solar panel, also called a photovoltaic module, refers to a photoelectric device that generates electricity directly from light, specifically sunlight. A solar panel is comprised a solar cell active layer, an encapsulation material, a front sheet and a back sheet.

The solar cell active layer may be an organic or inorganic semiconductor material that is capable of absorbing radiant energy and converting it into electrical energy. Solar cell active layers typically include multiple solar cells. Solar cell active layer materials include crystalline silicon, amorphous silicon, cadmium telluride, and copper indium gallium selenide (CIGS). The photoactive layer is disposed between a cathode and an anode. When incident light excites the photoactive material, electrons are released. The released electrons are captured in the form of electrical energy within the electric circuit created between the cathode and the anode.

The role of the encapsulation material in a solar panel is to protect the active layer from air and moisture, and to bond the front and back sheets to the active layer. One widely used encapsulation material is an ethylene-vinyl acetate film. During lamination at approximately 150° C., molten ethylene-vinyl acetate flows into gaps of the solar cell, encapsulating the solar cell active layer.

The role of the front sheet of a solar panel is to protect solar cells against mechanical impact and weathering while allowing light to pass to the active layer. To make full use of light energy, the front sheet must exhibit high light transmittance within a defined spectral range (e.g., between 400 and 1100 nm for crystalline silicon cells). The front sheets of existing solar panels are typically made from glass (usually low-iron tempered flint glass with a thickness of 3 to 4 mm) or polymeric materials.

The role of the back sheet of a solar panel is to protect solar cells and the encapsulation material or adhesive agent against moisture and oxidation. The back sheet must therefore exhibit an excellent moisture barrier and weather durability in addition to providing electrical insulation.

The multilayer laminated films most commonly used as solar panel back sheets comprise, for example, fluoropolymer film/polyethylene terephthalate film/fluoropolymer film laminates. Such film laminates use an organic solvent-based adhesive agent at the fluoropolymer film/polyethylene terephthalate film interface to bind the two films together. A significant drawback of this kind of laminated film is its use of an organic solvent-based adhesive agent. Bonding films with an organic solvent-based adhesive agent requires the use of drying ovens that are costly to purchase and operate and limit lamination speed. Organic solvents must be controlled in order to limit harm to the environment and to protect the health of operations staff. Even the organic solvent ethanol, which has low toxicity, can impact the health of operations staff. An organic solvent-free method is therefore desired for the manufacture of multilayer laminated films suitable for use as solar panel back sheets.

A variety of multilayer laminated films and associated manufacturing methods are known. For example, U.S. Pat. No. 5,139,878 discloses a multilayer film structure, comprising at least one fluoropolymer film (e.g., polytetrafluoroethylene), at least one thermoplastic polymer film (e.g., polyethylene terephthalate) with at least one layer of adhesive agent interposed between them (e.g., a polymer resin formed by an alkyl ester of an olefin having 2-8 carbon atoms and an α,β-ethylenically unsaturated carboxylic acid) where the multilayer laminated film is formed by co-extrusion. This multilayer laminated film is said to display high adhesive strength and good moisture and gas barrier properties, and is disclosed as being suitable for use as a packaging material for foodstuffs and medications. While such multilayer laminated films exhibit the moisture and gas barrier properties needed for packaging materials, they do not satisfy the requirements of numerous other applications. For example, such laminated films do not satisfy the requirements for use as solar panel back sheets, in terms of their mechanical, dielectric, weather-resistance and other properties.

One approach that is employed to improve the properties of existing multilayer laminated films is modifying the thermoplastic polymer film by stretching the film. Stretching is known to significantly improve the properties of polymer films, such as polyethylene terephthalate, including their barrier and optical properties, high and low temperature-resistance, and dimensional stability. However, melt co-extrusion methods used for the lamination of fluoropolymer and thermoplastic polymer is not suited to the lamination of pre-stretched thermoplastic polymer layers. There is a need for new lamination methods suitable for stretched films, and that use little or no organic solvents.

Various methods for binding fluoropolymer and non-fluorinated (or substantially non-fluorinated) polymer layers together are known. For example, U.S. Pat. No. 6,767,948 employs a crown ether catalyst to bind fluoropolymer and substantially non-fluorinated polymer together and provide the desired adhesive strength. However, the use of crown ether catalyst poses some of the same environmental and health issues that are present with organic solvent-based adhesives.

Extrusion lamination is a lamination method wherein molten resin is extruded through a die and coated on other substrates to make a laminated film. Three principal extrusion lamination methods are mono-layer extrusion lamination, tandem or multiplex extrusion lamination, and co-extrusion lamination. Compared to other lamination methods, extrusion lamination has the advantages of being fast, possessing high production efficiency, and low processing costs. Extrusion lamination is used to manufacture packaging materials. It has been reported that when a polyurethane adhesive agent (YH4501 of Beijing Comens Chemical Co. Ltd) is employed in the production of laminated polyethylene films by extrusion lamination, the adhesive strength of the polyurethane adhesive agent depends to a large extent on the processing techniques employed in the production of polyethylene (http://food.icxo.com/htmlnews/2004/09/08/325,139.htm). Key factors include melting temperature, aerial gap between nozzle and roller, operating speed, degree of corona treatment and amount of primer coating. Relatively high extrusion temperatures were found to increase adhesive strength but reduce heat seal performance.

However, methods required to combine a fluoropolymer film and a non-fluorinated polymer film, such as a stretched thermoplastic film, by extrusion lamination are still needed. Owing to the special surface properties of fluoropolymers, such as their extremely low surface energy, extremely low surface activity and poor adhesion, methods suitable for laminating polyethylene film to other polymer films by extrusion lamination are not necessarily suited for laminating fluoropolymer and non-fluorinated polymers, or for obtaining laminates with the desired laminate strength and weather durability needed for solar panel back sheets.

Therefore laminates comprising a stretched thermoplastic polymer film and fluoropolymer film are need that do not employ no organic solvents or catalysts in the production process.

### SUMMARY OF THE INVENTION

The present invention provides a method for the manufacturing of multilayer laminated films suitable for use as solar panel back sheets. This method does not require the use of organic solvent or organic catalyst. The invention also provides a solar panel, which uses the multilayer laminated film back sheet manufactured by means of the method of the present invention.

Thus, one aspect of the invention relates to a method for the manufacturing of multilayer laminated films, comprising:

(a) providing a fluoropolymer film;

(b) providing a stretched polyester film;

(c) providing an ethylene copolymer; and

(d) forming a fluoropolymer/ethylene copolymer/stretched polyester multilayer laminated film by extrusion lamination at a temperature of 270° C. or higher.

The ethylene copolymer is a copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight, preferably accounting for 65-85% by weight, and ideally accounting for 70-80% by weight.

Another aspect of the invention relates to a fluoropolymer/ethylene copolymer/stretched polyester multilayer laminated film formed by means of the above method.

Another aspect of the invention relates to a solar panel, which comprises a front sheet, a solar cell circuit and a back sheet, wherein the back sheet is the fluoropolymer/ethylene polymer/stretched polyester multilayer laminated film of the present invention.

### BRIEF DESCRIPTION OF THE DRAWINGS

FIG. 1 is a schematic illustration of a disclosed method for forming a solar panel back sheet material.

FIG. 2 is a schematic illustration of another disclosed method for forming a solar panel back sheet material.

### DETAILED DESCRIPTION OF THE INVENTION

The disclosed method employs extrusion lamination to form a fluoropolymer/ethylene copolymer/stretched polyester multilayer laminated film by melt-extrusion of the ethylene copolymer between the fluoropolymer layer and the stretched polyester layer, followed by lamination cooling. The adhesive strength of the laminated film depends upon the composition of the ethylene copolymer.

Fluoropolymer Layer

The multilayer laminated film described herein comprises a fluoropolymer layer. There are no specific restrictions on the fluoropolymer used. It can be any fluoropolymer known in the art, including homopolymers of fluorinated monomers, copolymers of fluorinated monomers, or copolymers of a fluorinated monomer and a non-fluorinated monomer, as long as monomer units derived from the fluorinated monomer in the copolymer account for more than 20% by weight, preferably accounting for 40-99% by weight, and ideally accounting for 55-98% by weight.

In one embodiment of the present invention, the fluoropolymer includes polymers or copolymers containing monomer units derived from fluoroethylene monomer, difluoroethylene monomer, 1,1-difluoroethylene monomer and/or perfluoroethylene monomer.

For example, the fluoropolymer may be fluoroethylene homopolymer, 1,1-difluoroethylene homopolymer, 1,2-difluoroethylene homopolymer, fluoroethylene/non-fluorinated C₂₋₄ mono-olefin copolymer, 1,1-difluoroethylene/non-fluorinated C₂₋₄ mono-olefin copolymer, hexafluoropropylene/fluoroethylene copolymer, hexafluoropropylene/1,1-difluoroethylene copolymer, hexafluoropropylene/1,2-difluoroethylene copolymer, tetrafluoroethylene/fluoroethylene copolymer, tetrafluoroethylene/1,1-difluoroethylene copolymer, tetrafluoroethylene/1,2-difluoroethylene copolymer, trifluorochloroethylene/fluoroethylene copolymer, or trifluorochloroethylene/1,1-difluoroethylene copolymer, trifluorochloroethylene/1,2-difluoroethylene copolymer among others.

In another embodiment of the present invention, the fluoropolymer includes polymers or copolymers containing monomer units derived from hexafluoropropylene monomer, tetrafluoroethylene monomer, trifluorochloroethylene monomer and/or other perfluoro-olefin monomers.

For example, the fluoropolymer may be hexafluoropropylene homopolymer, tetrafluoroethylene homopolymer, trifluorochloroethylene homopolymer, ethylene/tetrafluoroethylene copolymer, tetrafluoroethylene/propylene copolymer, trifluorochloroethylene/ethylene copolymer, ethylene/tetrafluoroethylene/hexafluoropropylene copolymer among others.

Fluoropolymers suitable for use in the present invention also include blends of two or more of the above polymers or copolymers. The fluoropolymer layer may also include minor amounts of other polymers and/or additives. The fluoropolymer layer is preferably comprised of at least 60 weight percent, and more preferably at least 80 weight percent, and ideally at least 90 weight percent of one or more of the above fluoropolymers based on the total weight of the fluoropolymer layer. Additives may include, for example, light stabilizer, UV stabilizers, thermal stabilizers, anti-hydrolytic agents, light reflection agents, pigments, titanium dioxide, dyes, and slip agents. Preferred fluoropolymer films have a tensile modulus that is greater than 150 KPsi. Suitable fluoropolymer films are commercially available. For example, polyfluoroethylene film is sold by DuPont, USA, under the trade name Tedlar®.

One or more layers of metallic, metal oxide or non-metal oxide surface coating can also be incorporated on one or two main surfaces of the above-mentioned fluoropolymer substrate, forming a fluoropolymer substrate with a metallic, metal oxide and/or non-metal oxide layer on the surface. The thickness of the metal oxide layer or non-metal oxide layer typically measures between 50 Å and 4000 Å, and preferably between 100 Å and 1000 Å. There are no specific restrictions on the thickness of a metal layer. It may be a thickness conventionally used in the art.

There are no specific restrictions on the metal oxides or non-metal oxides used. The oxides may be any metal oxide or non-metal oxide commonly used in the art. In disclosed embodiments of the present invention, the metal oxides or non-metal oxides employed comprise silicon oxides (SiOₓ, X=1-2) and aluminum oxides (AiOₓ, x=0.5-1.5). In one embodiment of the present invention, the above-mentioned oxide layer is deposited on one or two surfaces of the fluoropolymer by means of vapor deposition.

There are no specific restrictions on the metal layer used. It may be any metal layer commonly used in the art, such as silver foil, aluminum foil, tin foil, or copper foil. Aluminum foil and copper foil are most commonly selected on the basis of cost and other factors. The surface of fluoropolymer substrate may be laminated to the metal foil, where the thickness of the foil is in the range of 5-30 μm, or preferably 8-25 μm. There are no specific restrictions on the lamination method used. In one embodiment of the present invention, a 25 μm thick aluminum foil is laminated to a fluoropolymer substrate with the use of an extruded ethylene copolymer resin adhesive as described below.

The total thickness of the fluoropolymer substrate with a layer of metal or metal oxide/non-metal oxide laminated to its surfaces is in the range of 8-100 μm, preferably being 10-50 μm, and ideally 12-40 μm.

In another preferred embodiment of the present invention, the above-mentioned metallic, metal oxide and non-metal oxide layers are incorporated on one surface of the fluoropolymer substrate, while the second surface of the fluoropolymer substrate is in contact with the ethylene copolymer adhesive utilized in this invention.

### Polyester Layer

The laminated film described herein also comprises a polyester layer. When polyester is used as the substrate, there are no specific restrictions on the type of polyester used. It may be any polyester film layer known in the art, or a laminated film of two or more layers of polyester film. In one embodiment of the present invention, the polyester substrate has a total thickness in the range of 50-350 μm, preferably being 75-300 μm, and ideally 100-250 μm.

Non-limiting examples of polyester materials suitable for use as the substrate of the present invention include, for example:

PolyC₂₋₆alkylene terephthalate, preferably polyC₂₋₄alkylene terephthalates, such as polyethylene terephthalate (PET), polytrimethylene terephthalate, polybutylene terephthalate, polyhexamethylene terephthalate, polyethylene phthalate, polytrimethylene phthalate, polybutylene phthalate, polyhexamethylene phthalate etc, and ideally, polyethylene terephthalate;

PolyC₂₋₆ alkylene glycol naphthalate, preferably polyC₂₋₄alkylene glycol naphthalates, such as polyethylene naphthalate, polytrimethylene naphthalate, polybutylene naphthalate, etc; or

Blends and copolymers of two or more of the above materials.

As disclosed herein, the polyester layer comprises a stretched polyester film. As used herein with regard to polymer films, “stretched” means a polymer film that has been stretched in at least one direction by at least half of its original length. Polymer films most suitable for use in the invention have undergone mono-axial and/or biaxial stretching. The stretch ratio of mono-axially stretched polymer films is usually 2-4 times, and is preferably in the range of 2.5-3.5 times, while the longitudinal stretch ratio for biaxially stretched polymer films is usually 2-4 times, and is preferably in the range of 2.5-3.5 times; the transverse stretch ratio is usually 2-4 times, and is preferably in the range of 2.5-3.5 times. Suitable stretched polyester films are also commercially available. For example, stretched polyethylene terephthalate film may be purchased from DuPont Teijin Films.

The polyester layer may also include minor amounts of other polymers and/or additives. The polyester layer is preferably comprised of at least 60 weight percent, and more preferably at least 80 weight percent, and ideally at least 90 weight percent of one or more polyester polymers. Additives may include, for example, light stabilizer, UV stabilizers, thermal stabilizers, anti-hydrolytic agents, light reflection agents, pigments, titanium dioxide, dyes, and slip agents.

One or more layers of metallic, metal oxide or non-metal oxide surface coating can also be incorporated on one or two main surfaces of the above-mentioned polyester film, forming a polyester layer with metallic, metal oxide and/or non-metal oxide layer on the surface.

The thickness of the metal oxide layer or non-metal oxide layer typically measures between 50 Å and 4000 Å, and preferably between 100 Å and 1000 Å. There are no specific restrictions on the metal oxides or non-metal oxides used. The oxide may be any metal oxide or non-metal oxide commonly used in the art. In one embodiment of the present invention, the metal oxides or non-metal oxides employed comprise silicon oxides (SiOₓ, X=1-2) and aluminum oxides (AlOₓ, x=0.5-1.5). In one embodiment of the present invention, the above-mentioned oxide layer is deposited on one or two surfaces of the polyester layer by means of vapor deposition.

There are no specific restrictions on the metal layer that may be used. It may be any metal layer commonly used in the art, such as silver foil, aluminum foil, tin foil, or copper foil. Aluminum foil and copper foil are most commonly selected on the basis of cost and other factors. The surface of the polyester film may be laminated to a metal foil where the thickness of the foil is in the range of 5-30 μm, or preferably 8-25 μm. There are no specific restrictions on the lamination method used. In one embodiment of the present invention, a 25 μm thick aluminum foil is laminated to a 250 μm thick PET film with the use of an extruded ethylene copolymer resin as described below. In another embodiment, an additional copper foil is laminated to the opposite side of the PET film with the use of an extruded ethylene copolymer resin as described below.

The total thickness of the polyester layer with a layer of metal or metal oxide/non-metal oxide laminated on its surfaces is usually in the range of 8-20 μm. When in use, the polyester with the metal or oxide layer is usually laminated together with a conventional polyester layer. There are no specific restrictions on the lamination method used. It may be any method used in the art. In one embodiment of the present invention, one or two 12 μm thick PET films with aluminum oxide coatings on the main surfaces are laminated to a 250 μm thick PET film by contact between coated and uncoated PET surfaces and the use of an adhesive agent.

Ethylene Copolymer Adhesive Layer

The ethylene copolymer adhesive layer described herein is also called ethylene copolymer layer or ethylene copolymer middle layer. The ethylene copolymer used in the ethylene copolymer adhesive layer includes a copolymer of ethylene and another α-olefin. The ethylene content in the copolymer accounts for 60-90% by weight, preferably accounting for 65-88% by weight, and ideally accounting for 70-85% by weight of the ethylene copolymer. The other comonomer(s) preferably constitute 10-40% by weight, preferably accounting for 12-35% by weight, and ideally accounting for 15-30% by weight of the ethylene copolymer. The ethylene copolymer adhesive layer is comprised of at least 70 weight percent of the ethylene copolymer. The ethylene copolymer may be blended with up to 30% by weight, based on the weight of the adhesive layer, of other thermoplastic polymers such as polyolefins, as for example linear low density polyethylene, in order to obtain desired properties. Suitable materials used for forming the ethylene copolymer of the adhesive layer are selected from the following groups:

ethylene-C₁₋₄ alkyl methacrylate copolymers and ethylene-C₁₋₄ alkyl acrylate copolymers, for example, ethylene-methyl methacrylate copolymers, ethylene-methyl acrylate copolymers, ethylene-ethyl methacrylate copolymers, ethylene-ethyl acrylate copolymers, ethylene-propyl methacrylate copolymers, ethylene-propyl acrylate copolymers, ethylene-butyl methacrylate copolymers, ethylene-butyl acrylate copolymers, and mixtures of two or more copolymers thereof, wherein copolymer units resulting from ethylene account for 60%-90%, preferably 65%-88%, by total weight of each copolymer;

ethylene-methacrylic acid copolymers, ethylene-acrylic acid copolymers, and blends thereof, wherein copolymer units resulting from ethylene account for 60%-90%, preferably 65%-88%, by total weight of each copolymer;

ethylene-maleic anhydride copolymers, wherein copolymer units resulted from ethylene account for 60-90%, preferably 65-88%, by total weight of the copolymer;

copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers;

polybasic polymers formed by ethylene with at least two co-monomers selected from C₁₋₄ alkyl methacrylate, C₁₋₄ alkyl acrylate, ethylene-methacrylic acid, ethylene-acrylic acid, and ethylene-maleic anhydride, non-restrictive examples of which include, for example, terpolymers of ethylene-methyl acrylate-methacrylic acid (wherein copolymer units resulting from methyl acrylate account for 2-30% by weight and copolymer units resulting from methacrylic acid account for 1-30% by weight), terpolymers of ethylene-butyl acrylate-methacrylic acid (wherein copolymer units resulting from butyl acrylate account for 2-30% by weight and copolymer units resulting from methacrylic acid account for 1-30% by weight), terpolymers of ethylene-propyl methacrylate-acrylic acid (wherein copolymer units resulting from propyl methacrylate account for 2-30% by weight and copolymer units resulting from acrylic acid account for 1-30% by weight), terpolymers of ethylene-methyl acrylate-acrylic acid (wherein copolymer units resulting from methyl acrylate account for 2-30% by weight and copolymer units resulted from acrylic acid account for 1-30% by weight), terpolymers of ethylene-methyl acrylate-maleic anhydride (wherein copolymer units resulting from methyl acrylate account for 2-30% by weight and copolymer units resulting from maleic anhydride account for 0.2-10% by weight), terpolymers of ethylene-butyl acrylate-maleic anhydride (wherein copolymer units resulting from butyl acrylate account for 2-30% by weight and copolymer units resulted from maleic anhydride account for 0.2-10% by weight), and terpolymers of ethylene-acrylic acid-maleic anhydride (wherein copolymer units resulting from acrylic acid account for 2-30% by weight and copolymer units resulting from maleic anhydride account for 0.2-10% by weight);

copolymers formed by ethylene and glycidyl methacrylate with at least one co-monomer selected from C₁₋₄ alkyl methacrylate, C₁₋₄ alkyl acrylate, ethylene-methacrylic acid, ethylene-acrylic acid, and ethylene-maleic anhydride, non-restrictive examples of which include, for example, terpolymers of ethylene-butyl acrylate-glycidyl methacrylate, wherein copolymer units resulting from butyl acrylate account for 2-30% by weight and copolymer units resulting from glycidyl methacrylate account for 1-15% by weight;

and blends of two or more above-described materials.

In embodiments of the present invention, the ethylene copolymer adhesive layer comprises an ethylene copolymer formed from ethylene and one or more co-monomers, the co-monomers being selected from a group consisting of methacrylate, methyl acrylic ester, ethyl acrylic ester, propyl acrylic ester, butyl acrylic ester, ethylene hydrogen maleate, glycidyl methacrylate, methacrylic acid glyceride and maleic anhydride.

In other embodiments, the ethylene copolymer is an ethylene-(meth)acrylate-(meth)acrylic acid terpolymer such as ethylene-methyl acrylate-metharcylic acid terpolymer, ethylene-butyl acrylate-metharcylic acid terpolymer, ethylene-n butyl acrylate-methacrylic acid terpolymer, ethylene-isobutyl acrylate-methacrylic acid terpolymer, ethylene-methyl acrylate-acrylic acid terpolymer, ethylene-butyl methacrylate-methacrylic acid terpolymer, or ethylene-propyl methacrylate-methacrylic acid terpolymer. In another embodiment, the ethylene copolymer is an ethylene-(meth)acrylate-glycidyl methacrylate terpolymer such as ethylene-butyl methacrylate-methacrylic acid glyceride terpolymer, ethylene-n butyl acrylate-glycidyl methacrylate, or ethylene-acrylic ester-glycidyl metharcylate terpolymer. In another embodiment, the ethylene copolymer is an ethylene-alkyl(meth)acrylate-maleic anhydride terpolymer such as ethylene-methyl methacrylate-maleic anhydride terpolymer, ethylene-n butyl acrylate-maleic anhydride terpolymer, ethylene-ethyl acrylate-maleic anhydride terpolymer, or ethylene-acrylic ester-maleic anhydride.

In another embodiment, the copolymer comprises copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers. Additionally, the ethylene copolymer comprises from about 3 weight % to about 25 weight % copolymerized units of the comonomer. The copolymer may be a dipolymer or a higher order copolymer, such as a terpolymer or tetrapolymer. Examples of suitable comonomers of the third polymer component include unsaturated anhydrides such as maleic anhydride, and itaconic anhydride; C₁-C₂₀ alkyl monoesters of butenedioc acids (e.g. maleic acid, fumaric acid, itaconic acid and citraconic acid), including methyl hydrogen maleate, ethyl hydrogen maleate, propyl hydrogen fumarate, and 2-ethylhexyl hydrogen fumarate; C₁-C₂₀alkyl diesters of butenedioic acids such as dimethylmaleate, diethylmaleate, and dibutylcitraconate, dioctylmaleate, and di-2-ethylhexylfumarate. Of these, maleic anhydride, ethyl hydrogen maleate and methyl hydrogen maleate are preferred. Maleic anhydride and ethyl hydrogen maleate are most preferred. Higher order copolymers that are examples of the third polymer component include terpolymers such as ethylene/methyl acrylate/ethyl hydrogen maleate, ethylene/butyl acrylate/ethyl hydrogen maleate and ethylene/octyl acrylate/ethyl hydrogen maleate.

Various known additives may be added to the ethylene copolymer layer to satisfy various different requirements. Suitable additives may include, for example, light stabilizer, UV stabilizers, thermal stabilizers, anti-hydrolytic agents, light reflection agents, pigments, titanium dioxide, dyes, and slip agents. There are no specific restrictions to the content of the additives in the ethylene copolymer adhesive layer, as long as the additives do not produce an adverse impact on the bonding layer or final adhesion properties of the laminated film.

Ethylene copolymers are also commercially available. For example, one may be purchased from E.I. du Pont de Nemours and Company under the trade-name Bynel®.

There are no specific restrictions on the thickness of individual layers used in the laminated film described herein. Thickness varies according to specific application. In one preferred embodiment of the present invention, the fluoropolymer layer has a thickness in the range of 20-50 μm, and is preferably in the range of 15-38 μm, the ethylene copolymer adhesive layer has a thickness in the range of 5-100 μm, and is preferably in the range of 20-50 μm, and the polyester film has a thickness of 50-300 μm, and is preferably in the range of 100-250 μm.

The ethylene copolymer adhesive layer itself may also be a two-layer, three-layer or multilayer material. It may be formed by means of co-extrusion, whereby a fluoropolymer film and a stretched polyester film are laminated together.

Lamination Method

The laminated film described herein is formed by means of an extrusion laminating method. The inventors of the present invention discovered that the adhesive strength established between layers of the laminated film formed by extrusion lamination depends on the composition of the ethylene copolymer. When the ethylene copolymer contains 10% or more co-monomer by weight, the adhesive strength of the formed laminated film significantly improves, typically exceeding 5 N/cm.

Thus, the method used in the manufacture of laminated films described herein comprises the following steps:

(a) providing a fluoropolymer film;

(b) providing a stretched polyester film;

(c) melt-extruding the ethylene copolymer between the above two films, with the melt temperature of the ethylene copolymer set at 270° C. or higher;

(d) laminating the two films together with the ethylene copolymer as a middle layer.

The fluoropolymer film is selected from the fluoropolymer layers described above, the stretched polyester film is selected from the stretched polyester layers described above, and the ethylene copolymer is selected from the ethylene copolymer adhesive layers described above.

In the method described herein, the melt temperature of the ethylene copolymer may be any temperature between 270° C. and the decomposition temperature of the ethylene copolymer, usually being in the range of 270-350° C., preferably in the range of 280-330° C., and ideally in the range of 290-310° C.

To further increase the adhesive strength of the obtained laminated layer, a surface treatment may be carried out on the fluoropolymer film, the polyester film or both. The surface treatment method employed may be any surface treatment known in the art, including corona treatment or a primer coating treatment.

The present invention also relates to a solar panel, which comprises a back sheet, a solar cell active layer, an encapsulation material and a front sheet, wherein the back sheet is made from the laminated film described herein.

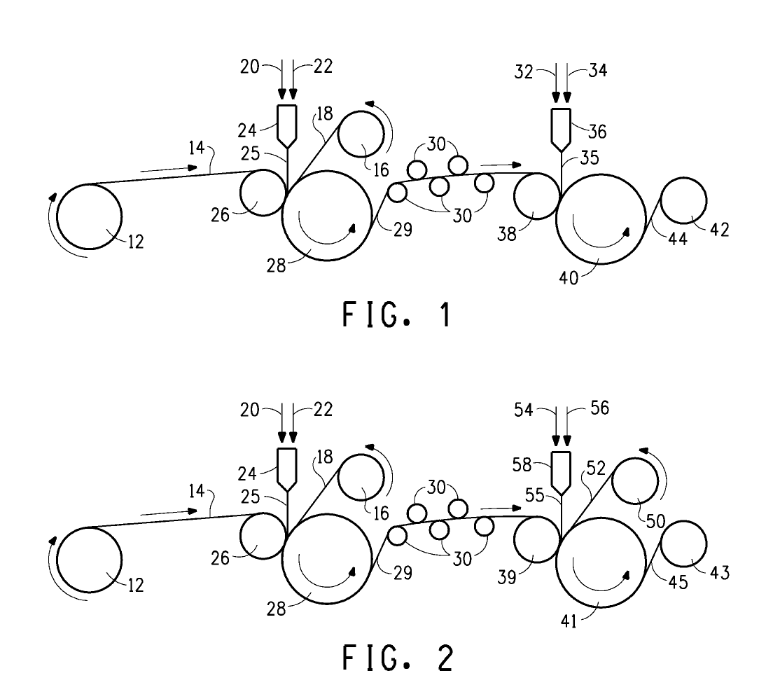

An illustrative method for forming the disclosed solar panel back sheet material is illustrated in FIG. 1. A fluoropolymer film 14 is fed from a roll 12 to a nip formed between the rolls 26 and 28. A stretched polyester film 18 is fed from the roll 16 to the same nip. The rolls 26 and 28 are lamination rollers as known in the art, and may have hard or flexible surfaces, and may be heated or cooled depending on the desired processing conditions. The ethylene copolymer adhesive layer 25 is extruded from an extruder 24 between the fluoropolymer film 14 and the stretched polyester film 18 just before the films enter the nip. The extruded copolymer adhesive layer 25 may be comprised of multiple co-extruded layers where each layer is designed to perform a specific function. For example, in FIG. 1, two different ethylene copolymer feeds 20 and 22 are fed to the extruder where the feed 20 forms an ethylene copolymer sub-layer designed to adhere to the fluoropolymer film, and where the feed 22 forms a distinct ethylene copolymer sub-layer designed to adhere to the polyester film. It is contemplated that the extruded copolymer adhesive layer 25 could be made with additional sub-layers with other functions such as joining the other sub-layers together or providing desired moisture barrier or insulating properties. When desired, the laminated film 29 can be collected on a collection roll after coming off the roll 28. In FIG. 1, another subsequent extrusion coating step is illustrated.

As shown in FIG. 1, the laminated film 29 is carried by the transfer rollers 30 to a second extruder 36 and a second nip formed between the rolls 38 and 40. The rolls 38 and 40 are coating rollers as known in the art, and may have hard or flexible surfaces, and may be heated or cooled depending on the desired processing conditions. The ethylene copolymer adhesive layer 35 is extruded from an extruded 36 onto the exposed surface of the stretched polyester film 18 of the laminated film 29. The extruded copolymer adhesive layer 35 may be comprised of multiple co-extruded layers where each layer is designed to perform a specific function. For example, in FIG. 1, two different ethylene copolymer feeds 32 and 34 are fed to the extruder where the feed 32 forms an ethylene copolymer sub-layer designed to adhere to the stretched polyester film, and where the feed 34 forms a distinct ethylene copolymer sub-layer designed to adhere an encapsulation layer, such as an ethylene vinyl acetate layer, of a solar panel to which the backsheet is to be adhered. It is contemplated that the extruded copolymer adhesive layer 35 could be made with additional sub-layers with other functions such as joining the other sub-layers together or providing desired moisture barrier or insulating properties. The laminated and coated film 44 is collected on the roller 42.

In another disclosed process, as shown in FIG. 2, a solar panel back sheet material is made in a single pass process where the back sheet comprises the following layers: fluoropolymer film/ethylene copolymer/polyester film/ethylene copolymer/fluoropolymer film. The fluoropolymer film/ethylene copolymer/polyester laminated film 29 is formed as described above with regard to FIG. 1. The laminated film 29 is carried by the transfer rollers 30 to a second extruder 58 and a second nip formed between the rolls 39 and 41. In addition, a second fluoropolymer film 52 is fed from the roll 50 to the nip formed by the rolls 39 and 41. The rolls 39 and 41 are lamination rollers as known in the art, and may have hard or flexible surfaces, and may be heated or cooled depending on the desired processing conditions. The ethylene copolymer adhesive layer 55 is extruded from an extruder 58 between the laminated film 29 and the second fluoropolymer film 52 just before the films enter the nip. The extruded copolymer adhesive layer 55 may be comprised of multiple co-extruded layers where each layer is designed to perform a specific function. For example, two different ethylene copolymer feeds 54 and 56 are fed to the extruder where the feed 54 forms an ethylene copolymer sub-layer designed to adhere to the exposed polyester layer of the laminated film 29, and where the feed 56 forms a distinct ethylene copolymer sub-layer designed to adhere to the second fluoropolymer film 52. It is contemplated that the extruded copolymer adhesive layer 55 could be made with additional sub-layers with other functions such as joining the other sub-layers together or providing desired moisture barrier or insulating properties. Where desired, the laminated fluoropolymer film/ethylene copolymer/polyester film/ethylene copolymer/fluoropolymer film 45 can be collected on a collection roll 43 after coming off the roll 41. In another disclosed alternative, the laminated fluoropolymer film/ethylene copolymer/polyester film/ethylene copolymer/fluoropolymer film 45 can be passed on transfer rollers to a coating extruder, like the extruder 36 in FIG. 1, where the exposed surface of one of the fluoropolymer films can be coated with an ethylene copolymer film designed to adhere to the encapsulation layer of a solar panel in the same manner as the polyester layer of the laminated film 29 is coated by the ethylene copolymer adhesive layer 55 in FIG. 1. In another alternative embodiment, a metal foil such as aluminum or copper foil can be adhered to the polyester layer 18 by replacing the second fluoropolymer film 52 in FIG. 2 with metal foil as described above.

The present invention is further illustrated by the following examples.

Test Methods

Peel Strength of Laminated Film. The peel strength of the bond established between layers of laminated film was measured using a tensile testing machine. The laminated film was cut into sample strips measuring 2.54 cm in width and 10 cm in length. The polyester layer was held in the upper clamp and substrate held in the lower clamp of a tensile tester for peel testing, and stretched at a rate of 5 in/min.

Peel Strength with Encapsulation Material. The peel strength of the bond established between the laminated film and the ethylene-vinyl acetate copolymer encapsulation material was measured using a tensile testing machine. A laminated film (with its fluoropolymer film lying outermost, and its polyester layer adjacent to the encapsulation film), an ethylene-vinyl acetate copolymer encapsulation film, and a piece of glass were laid in sequence and placed in a laminating machine for vacuum lamination cross-linking with operating conditions set at 145° C. for 15 min. The sample was then cut into sample strips measuring 2.54 cm in width and 10 cm in length. The back sheet laminated film was held in the upper clamp and the encapsulation material/glass layer held in the lower clamp of a tensile tester for peel testing, and stretched at a rate of 5 in/min.

### Example 1

Laminated Film of Polyfluoroethylene/Ethylene-Butyl Acrylate Copolymer/Biaxially Stretched Polyethylene Terephthalate

Corona treatment was carried out on a surface of a polyfluoroethylene film (25 μm thick, trade-name Tedlar®, obtained from DuPont of Wilmington, Del., USA) and a surface of a biaxially stretched polyethylene terephthalate film (250 μm thick, stretched 3.5 times in the longitudinal direction and 3 times in the transverse direction) using corona treatment equipment.

Using extrusion coating/laminating equipment produced by Davis Standard, a roll of the biaxially stretched polyethylene terephthalate film was unwound as the first layer, a roll of the polyfluoroethylene film was unwound as the second layer, and then an ethylene-butyl acrylate copolymer (25 μm thick, containing 17% by weight of butyl acrylate, with a melt index of 7, obtained from DuPont) was melt-extruded from the extruder (having a temperature profile of 180° C., 210° C., 250° C., 280° C. and 310° C. from feeder to die) into the gap separating the corona treated surfaces of the polyfluoroethylene film and the biaxially stretched polyethylene terephthalate film. A laminated film was obtained and wound after cooling. Its peel strength was tested after storage at room temperature for one week, with the result that no delamination was observed at 8 N/cm (at which point the polyfluoroethylene layer fractured).

The laminated film was placed in an environmental chamber at 85° C. and 85% RH for 1,000 hrs. Its peel strength was then tested, with the result that no delamination was observed at 8 N/cm (at which point the polyfluoroethylene layer fractured).

The peel strength of the bond between the obtained laminated film and a film of ethylene-vinyl acetate copolymer encapsulation material was tested according to the above method, and a peel strength of 5 N/cm was measured.

### Example 2

### Laminated Film of Polyfluoroethylene/Ethylene-Acrylic Acid Copolymer/Biaxially Stretched Polyethylene Terephthalate

Using the method of Example 1, corona treatment was carried out on a polyfluoroethylene film (25 μm thick, trade-name Tedlar®, obtained from DuPont) and a biaxially stretched polyethylene terephthalate film (250 μm thick, stretched 3.5 times in the longitudinal direction and 3 times in the transverse direction).

Using extrusion coating/laminating equipment produced by Davis Standard, a roll of the polyfluoroethylene film was unwound as the first layer, and then an ethylene-acrylic acid copolymer (25 μm, containing 12% by weight of acrylic acid, with a melt index of 13.5, obtained from DuPont) was melt-extruded from the extruder (having a temperature profile of 190° C., 230° C., 260° C., 290° C. and 320° C. from feeder to die) and attached to the interface between the polyfluoroethylene and biaxially stretched polyethylene terephthalate film. A laminated film was obtained and wound after cooling. The peel strength of the laminated film was tested after storage at room temperature for one week, with the result that no delamination was observed at 8 N/cm (at which point the polyfluoroethylene layer fractured).

After aging at 85° C. and 85% RH for 1,000 hrs, the peel strength of the polyfluoroethylene/biaxially stretched polyethylene terephthalate bond exceeded 8 N/cm (at which point the polyfluoroethylene layer fractured).

The peel strength of the bond between the obtained laminated film and a film of ethylene-vinyl acetate copolymer encapsulation material was tested according to the above method, and a result of 5 N/cm obtained.

### Comparative Example 1

### Laminated Film of Polyfluoroethylene/Ethylene-Methacrylic Acid Copolymer/Biaxially Stretched Polyethylene Terephthalate

Corona treatment was carried out on a polyfluoroethylene film (25 μm thick, trade-name Tedlar®, obtained from DuPont) and a biaxially stretched polyethylene terephthalate film (250 μm thick, stretched 3.5 times in the longitudinal direction and 3 times in the transverse direction) using corona treatment equipment.

Using extrusion laminating equipment produced by Davis Standard, a roll of the polyfluoroethylene film was unwound as the first layer, and a roll of the biaxially stretched polyethylene terephthalate film was unwound as the second layer, and then the ethylene-methacrylic acid copolymer (25 μm thick, containing 4% by weight of methacrylic acid, with a melt index of 7.5, purchased from DuPont) was melt-extruded from the extruder (having a temperature profile of 170° C., 200° C., 230° C., 260° C. and 290° C. from feeder to die) into the gap separating the polyfluoroethylene film and biaxially stretched polyethylene terephthalate film. A laminated film was obtained and wound after cooling. The peel strength of the laminated film was tested after storage at room temperature for one week with the result that delamination was observed at 0.5 N/cm.

### Comparative Example 2

### Laminated Film of Polyfluoroethylene/Ethylene-Methyl Acrylate Copolymer/Biaxially Stretched Polyethylene Terephthalate

Corona treatment was carried out on a polyfluoroethylene film (25 μm thick, trade-name Tedlar®, obtained from DuPont) and a biaxially stretched polyethylene terephthalate film (250 μm thick, stretched 3.5 times in longitudinal direction and 3 times in transverse direction) using corona treatment equipment.

Using extrusion laminating equipment produced by Davis Standard, a roll of the polyfluoroethylene film was unwound as the first layer, and a roll of the biaxially stretched polyethylene terephthalate film was unwound as the second layer, and then an ethylene-methyl acrylate copolymer (25 μm thick, containing 4.3% by weight of methyl acrylate, with a melt index of 1.1, obtained from DuPont) was melt-extruded from the extruder (having a temperature profile of 170° C., 200° C., 230° C., 260° C. and 290° C. from feeder to die) into the gap separating the polyfluoroethylene film and biaxially stretched polyethylene terephthalate film. A laminated film was obtained and wound after cooling. The peel strength of the laminated film was tested after storage at room temperature for one week with the result that delamination was observed at 0.8 N/cm.

### Example 3

### Laminated Film of Polyfluoroethylene/Ethylene-Acrylic Acid Copolymer/Biaxially Stretched Polyethylene Terephthalate/Polyfluoroethylene

Corona treatment was carried out on a polyfluoroethylene film (25 μm thick, trade-name Tedlar®, obtained from DuPont) and a biaxially stretched polyethylene terephthalate film (PET, 250 μm, stretched 3.5 times in the longitudinal direction and 3 times in the transverse direction) using the method of Example 1, with the exception that both surfaces of the PET were corona treated.

Using multi-die continuous extrusion coating/laminating equipment, a roll of the polyfluoroethylene film was unwound as the first layer, and an ethylene-acrylic acid copolymer (25 μm thick, containing 12% by weight of acrylic acid, with a melt index of 13.5, obtained from DuPont) was melt-extruded from the extruder (having a temperature profile of 190° C., 230° C., 260° C., 290° C. and 320° C. from feeder to die) and attached to the interface between the polyfluoroethylene film and the biaxially stretched polyethylene terephthalate film. The laminated film was pressed firmly and cooled before entering the second extrusion lamination zone, where another roll of the polyfluoroethylene film was unwound as the third layer, and then an ethylene-acrylic acid copolymer (25 μm thick, containing 12% by weight of acrylic acid, with a melt index of 13.5, obtained from DuPont) was melt-extruded from the extruder (having a temperature profile of 190° C., 230° C., 260° C., 290° C. and 320° C. from feeder to die) and attached to the interface between the polyfluoroethylene/PET and the second polyfluoroethylene film. The laminated film was pressed firmly, cooled and wound to obtain a laminated film of polyfluoroethylene/PET/polyfluoroethylene. The peel strength of the laminated film was tested after storage at room temperature for one week, with the result that no delamination was observed at 8 N/cm (at which point the polyfluoroethylene layer fractured).

After aging at 85° C. and 85% RH for 1,000 hrs, the peel strength of the polyfluoroethylene/biaxially stretched polyethylene terephthalate bond exceeded 8 N/cm (at which point the polyfluoroethylene layer fractured).

This method realized one-step continuous production of polyfluoroethylene/PET/polyfluoroethylene solar cell module back sheets, greatly increasing production efficiency.

The peel strength of the bond established between the resulting laminated film and a film of ethylene-vinyl acetate copolymer encapsulation material was tested according to the above method, and a peel strength of 7 N/cm was measured.

### Example 4

### Laminated Film of Polyfluoroethylene/Ethylene-Methyl Acrylate Copolymer/Biaxially Stretched Polyethylene Terephthalate/Ethylene-Methyl Acrylate Copolymer

Corona treatment was carried out on a polyfluoroethylene film (25 μm thick, trade-name Tedlar®, obtained from DuPont) and a biaxially stretched polyethylene terephthalate film (PET, 188 μm thick, stretched 3.5 times in the longitudinal direction and 3 times in the transverse direction) using the method of Example 1, with the exception that both surfaces of the PET were corona treated.

Using multi-die continuous extrusion coating/laminating equipment, a roll of the polyfluoroethylene film was unwound as the first layer, and an ethylene-methyl acrylate copolymer (25 μm thick, containing 20% by weight of methyl acrylate, with a melt index of 8, obtained from DuPont) was melt-extruded from the extruder (having a temperature profile of 160° C., 190° C., 220° C., 250° C. and 300° C. from feeder to die) and attached to the interface between the polyfluoroethylene film and the biaxially stretched polyethylene terephthalate film. The laminated film was pressed firmly and cooled before entering the second extrusion coating zone, where an ethylene-methyl acrylate copolymer (35 μm thick, containing 20% by weight of methyl acrylate, with a melt index of 8, obtained from DuPont) was then melt-extruded from the extruder (having a temperature profile of 160° C., 190° C., 220° C., 250° C. and 300° C. from feeder to die) and attached to the reverse surface of the PET, and then pressed firmly. A laminated film of polyfluoroethylene/ethylene-methyl acrylate copolymer/biaxially stretched polyethylene terephthalate/ethylene-methyl acrylate copolymer was obtained and wound after cooling.

The peel strength of the laminated film was tested after storage at room temperature for one week, with the result that no delamination was observed at 8 N/cm (at which point the polyfluoroethylene layer fractured).

After aging at 85° C. and 85% RH for 1,000 hrs, the peel strength of the polyfluoroethylene/biaxially stretched polyethylene terephthalate bond exceeded 8 N/cm (at which point the polyfluoroethylene layer fractured).

This method realized one-step continuous production of polyfluoroethylene/PET/polyfluoroethylene solar cell module back sheets back sheets, greatly increasing production efficiency.

The peel strength of the bond established between the resulting laminated film and a film of ethylene-vinyl acetate copolymer encapsulation material was tested according to the above method, and a peel strength of 80 N/cm was measured.

### Example 5

### Laminated Film of Polyfluoroethylene/Ethylene-Methyl Acrylate Copolymer/Biaxially Stretched Polyethylene Terephthalate/Ethylene-Methyl Acrylate Copolymer/Low Density Polyethylene Copolymer

Corona treatment was carried out on a polyfluoroethylene film (25 μm thick, trade-name Tedlar®, obtained from DuPont) and a biaxially stretched polyethylene terephthalate film (PET, 188 μm thick, stretched 3.5 times in the longitudinal direction and 3 times in the transverse direction) using the method of Example 1, with the exception that both surfaces of the PET were treated.

Using multi-die continuous co-extrusion coating/laminating equipment, a roll of the polyfluoroethylene film was unwound as the first layer, and an ethylene-methyl acrylate copolymer (25 μm thick, containing 20% by weight of methyl acrylate, with a melt index of 8, obtained from DuPont) was melt-extruded from the extruder (having a temperature profile of 160° C., 190° C., 220° C., 250° C. and 300° C. from feeder to die) and attached to the interface between the polyfluoroethylene film and the biaxially stretched polyethylene terephthalate film. The laminated film was pressed firmly and cooled before entering the second extrusion coating zone. An ethylene-methyl acrylate copolymer (35 μm thick, containing 20% by weight of methyl acrylate, with a melt index of 8, obtained from DuPont) was melt-extruded from the extruder (having a temperature profile of 160° C., 190° C., 220° C., 250° C. and 300° C. from feeder to die) along with a low density polyethylene (50 μm thick, with a melt index of 7, purchased from Dow Chemical) that was melt-extruded (at a temperature profile of 160° C., 190° C., 220° C., 250° C. and 300° C. from feeder to die) to form a co-extruded melt. The ethylene-methyl acrylate side of the co-extruded melt was attached to the reverse surface of the PET and pressed firmly. A laminated film of polyfluoroethylene/ethylene-methyl acrylate copolymer/biaxially stretched polyethylene terephthalate/ethylene-methyl acrylate copolymer/low density polyethylene copolymer laminated film was obtained and wound after cooling. The peel strength of the laminated film was tested after storage at room temperature for one week, with the result that no delamination was observed at 8 N/cm (at which point the polyfluoroethylene layer fractured).

After aging at 85° C. and 85% RH for 1,000 hrs, the peel strength of the polyfluoroethylene/biaxially stretched polyethylene terephthalate bond exceeded 8 N/cm (at which point the polyfluoroethylene layer fractured).

The peel strength of the bond established between the resulting laminated film and a film of ethylene-vinyl acetate copolymer encapsulation material was tested according to the above method, and a peel strength of 56 N/cm was measured.

### Example 6

### Laminated Film of Polyfluoroethylene/Ethylene-Methyl Acrylate Copolymer/Biaxially Stretched Polyethylene Terephthalate/Ethylene Methyl Acrylate Copolymer/Ethylene Methyl Acrylate Copolymer

Corona treatment was carried out on a polyfluoroethylene film (25 μm thick, trade-name Tedlar®, obtained from DuPont) and a biaxially stretched polyethylene terephthalate film (PET, 188 μm thick, stretched 3.5 times in longitudinal direction and 3 times in transverse direction) using the method of Example 1, with the exception that both surfaces of the PET film were corona treated.

Using multi-die continuous co-extrusion coating/laminating equipment, a roll of the polyfluoroethylene film was unwound as the first layer, and an ethylene-methyl acrylate copolymer (25 μm thick, containing 20% by weight of methyl acrylate, with a melt index of 8, obtained from DuPont) was melt-extruded from the extruder (having a temperature profile of 160° C., 190° C., 220° C., 250° C. and 300° C. from feeder to die) and attached to the interface between the polyfluoroethylene film and the biaxially stretched polyethylene terephthalate film. The laminated film was pressed firmly and cooled before entering a second extrusion coating zone. An ethylene-methyl acrylate copolymer (35 μm thick, containing 20% by weight of methyl acrylate, with a melt index of 8, obtained from DuPont) was melt-extruded from the extruder (having a temperature profile of 160° C., 190° C., 220° C., 250° C. and 300° C. from feeder to die), and in another parallel extruder, an ethylene-methyl acrylate copolymer (35 μm thick, containing 9% by weight of methyl acrylate, with a melt index of 6, obtained from DuPont) was melt-extruded from the extruder (having a temperature profile of 160° C., 190° C., 220° C., 250° C. and 300° C. from feeder to die) to form a co-extruded melt. The ethylene-methyl acrylate (20%) copolymer side of the co-extruded melt was attached to the reverse surface of the PET and pressed firmly. A laminated film of polyfluoroethylene/ethylene-methyl acrylate copolymer/biaxially stretched polyethylene terephthalate/ethylene-methyl acrylate copolymer/ethylene-methyl acrylate copolymer laminated film was obtained and wound after cooling. The peel strength of the laminated film was tested after storage at room temperature for one week, with the result that no delamination was observed at 8 N/cm (at which point the polyfluoroethylene layer fractured).

After aging at 85° C. and 85% RH for 1,000 hrs, the peel strength of the polyfluoroethylene/biaxially stretched polyethylene terephthalate bond exceeded 8 N/cm (at which point the polyfluoroethylene layer fractured).

The peel strength of the bond established between the resulting laminated film and a film of ethylene-vinyl acetate copolymer encapsulation material was tested according to the above method, and a peel strength of 71N/cm was measured.

### Example 7

### Laminated Film of Polyfluoroethylene/Ethylene-Methyl Acrylate Copolymer/Aluminum Sesquioxide Coated Biaxially Stretched Polyethylene Terephthalate Laminated Film/Biaxially Stretched Polyethylene Terephthalate

Corona treatment was carried out on a polyfluoroethylene film (25 μm thick, trade-name Tedlar®, obtained from DuPont) using the method of Example 1.

An aluminum sesquioxide coated biaxially stretched polyethylene terephthalate laminated film (12 μm thick, purchased from Toray, Japan) was laminated to a biaxially stretched polyethylene terephthalate film with the use of an adhesive agent.

Using extrusion laminating equipment produced by Davis Standard, a roll of the polyfluoroethylene film was unwound as the first layer, and a roll of composite film combining the aluminum sesquioxide coated biaxially stretched polyethylene terephthalate laminated film and the biaxially stretched polyethylene terephthalate film was unwound as the second layer. An ethylene-methyl acrylate copolymer (25 μm thick, containing 20% by weight of methyl acrylate, with a melt index of 8, obtained from DuPont) was then melt-extruded from an extruder (having a temperature profile of 190° C., 230° C., 260° C., 290° C. and 310° C. from feeder to die) and attached to the interface between the polyfluoroethylene film and the aluminum sesquioxide coated biaxially stretched polyethylene terephthalate film. A laminated film was obtained and wound after cooling. The peel strength of the film was tested after storage at room temperature for one week, with the result that no delamination was observed at 8 N/cm (at which point the polyfluoroethylene layer fractured).

After aging at 85° C. and 85% RH for 1,000 hrs, the peel strength of the polyfluoroethylene/biaxially stretched polyethylene terephthalate bond exceeded 8 N/cm (at which point the polyfluoroethylene layer fractured).

The peel strength of the bond established between the resulting laminated film and a film of ethylene-vinyl acetate copolymer encapsulation material was tested according to the above method, and a peel strength of 5 N/cm was measured.

### Embodiment 8

### Laminated Film of Polyfluoroethylene/Ethylene-Methyl Acrylate Copolymer/Aluminum Foil/Biaxially Stretched Polyethylene Terephthalate

Corona treatment was carried out on a polyfluoroethylene film (25 μm thick, trade-name Tedlar®, obtained from DuPont) using the method of Example 1.

An aluminum foil (25 μm thick, purchased from Alcoa, USA) was laminated to a biaxially stretched polyethylene terephthalate film with the use of an adhesive agent.

Using extrusion laminating equipment produced by Davis Standard, a roll of the polyfluoroethylene film was unwound as the first layer, and a roll of composite film combining the aluminum foil and the biaxially stretched polyethylene terephthalate film was unwound as the second layer. An ethylene-methyl acrylate copolymer (25 μm thick, containing 20% by weight of methyl acrylate, with a melt index of 8, obtained from DuPont) was then melt-extruded from the extruder (having a temperature profile of 190° C., 230° C., 260° C., 290° C. and 310° C. from feeder to die) and attached to the interface between the polyfluoroethylene film and the aluminum foil. A laminated film was obtained and wound after cooling. The peel strength of the laminated film was tested after storage at room temperature for one week, with the result that no delamination was observed at 6 N/cm (at which point the polyfluoroethylene layer fractured).

After aging at 85° C. and 85% RH for 1,000 hrs, the peel strength of the laminated film exceeded 6 N/cm (at which point the polyfluoroethylene layer fractured).

The peel strength of the bond established between the resulting laminated film and a film of ethylene-vinyl acetate copolymer encapsulation material was tested according to the above method, and a peel strength of 5 N/cm was measured.

### Example 9

### Laminated Film of Polyfluoroethylene/Ethylene-Methyl Acrylate Copolymer/Biaxially Stretched Polyethylene Terephthalate

Corona treatment was carried out on a polyfluoroethylene film (25 μm thick, trade-name Tedlar®, obtained from DuPont) and a biaxially stretched polyethylene terephthalate film (250 μm thick, stretched 3.5 times in the longitudinal direction and 3 times in the transverse direction) using the method of Example 1.

Using extrusion coating/laminating equipment with online prime coating function produced by Egan, a biaxially stretched polyethylene terephthalate film was prime coated with A-131X primer (product of Mica, USA, to a coating thickness of 0.2 μm). A roll of the polyfluoroethylene film was unwound as the second layer, and then an ethylene-methyl acrylate copolymer (25 μm thick, containing 12% by weight of methyl acrylate, with a melt index of 13.5, purchased from DuPont) was melt-extruded from the extruder (having a temperature profile of 190° C., 230° C., 260° C., 290° C. and 310° C. from feeder to die) and attached to the interface between the polyfluoroethylene and the prime coated biaxially stretched polyethylene terephthalate film. A laminated film was obtained and wound after cooling. The peel strength of the laminated film was tested after storage at room temperature for one week, with the result that no delamination was observed at 8 N/cm (at which point the polyfluoroethylene layer fractured).

After aging at 85° C. and 85% RH for 1,000 hrs, the peel strength of the laminated film exceeded 8 N/cm (at which point the polyfluoroethylene layer fractured).

The peel strength of the bond established between the resulting laminated film and a film of ethylene-vinyl acetate copolymer encapsulation material was tested according to the above method, and a peel strength of 5 N/cm was measured.

1. A method for manufacturing a back sheet material for a solar module, comprising:
(a) providing a fluoropolymer film;
(b) providing a stretched polyester film;
(c) providing a copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight; and
(d) extruding an adhesive layer comprised of at least 70% by weight of the ethylene copolymer of step (c), based on the weight of the adhesive layer, at a temperature of 270° C. or higher between the fluoropolymer film and the stretched polyester film, and pressing the ethylene copolymer between the fluoropolymer film and the stretched polyester film to form a fluoropolymer/ethylene copolymer/stretched polyester multilayer laminated film for a solar module back sheet.

2. A method as claimed in claim 1, wherein the fluoropolymer is selected from a group consisting of fluoroethylene homopolymer, 1,1-difluoroethylene homopolymer, 1,2-difluoroethylene homopolymer, fluoroethylene/non-fluorinated C₂₋₄ mono-olefin copolymer, 1,1-difluoroethylene/non-fluorinated C₂₋₄ mono-olefin copolymer, hexafluoropropylene/fluoroethylene copolymer, hexafluoropropylene/1,1-difluoroethylene copolymer, hexafluoropropylene/1,2-difluoroethylene copolymer, tetrafluoroethylene/fluoroethylene copolymer, tetrafluoroethylene/1,1-difluoroethylene copolymer, tetrafluoroethylene/1,2-difluoroethylene copolymer, trifluorochloroethylene/fluoroethylene copolymer, trifluorochloroethylene/1,1-difluoroethylene copolymer, trifluorochloroethylene/1,2-difluoroethylene copolymer, or a blend of two or more of the above polymers or copolymers.

3. A method as claimed in claim 1, wherein the fluoropolymer is selected from a group consisting of polymers or copolymers containing monomer units derived from hexafluoropropylene, tetrafluoroethylene and trifluorochloroethylene.

4. A method as claimed in claim 1, wherein the polyester film comprises poly C₂₋₆ alkyl benzenedicarboxylate.

5. A method as claimed in claim 4, wherein the polyester is selected from a group consisting of polyethylene terephthalate, polytrimethylene terephthalate, polybutylene terephthalate, polyhexamethylene terephthalate, polyethylene phthalate, polytrimethylene phthalate, polybutylene phthalate, polyhexamethylene phthalate or a copolymer or blend of two or more of the above.

6. A method as claimed in claim 1, wherein the polyester film undergoes mono-axial and biaxial stretching.

7. A method as claimed in claim 1, wherein the ethylene copolymer is selected from a group consisting of ethylene-methyl methacrylate copolymer, ethylene-ethyl methacrylate copolymer, ethylene-propyl methacrylate copolymer, ethylene-butyl methacrylate copolymer, ethylene-methyl acrylate copolymer, ethylene-ethyl acrylate copolymer, ethylene-propyl acrylate copolymer, ethylene-butyl acrylate copolymer or a blend of two or more of them in any ratio.

8. A method as claimed in claim 1, wherein the ethylene copolymer comprises an ethylene copolymer formed by ethylene and one or more co-monomers, the co-monomer being selected from a group consisting of methyl methacrylate, methyl acrylic ester, ethyl methacrylate, ethyl acrylic ester, propyl methacrylate, propyl acrylic ester, butyl methacrylate, butyl acrylic ester, methacrylic acid glyceride, methyl hydrogen maleate, ethyl hydrogen maleate, and maleic anhydride.

9. A method as claimed in claim 1, wherein the ethylene copolymer is selected from a group consisting of ethylene-(meth)acrylate-(meth)acrylic acid terpolymers, ethylene-(meth)acrylate-glycidyl methacrylate terpolymers, and ethylene-alkyl(meth)acrylate-maleic anhydride terpolymers.

10. A method as claimed in claim 1, wherein one or more metallic layers, metal oxide layers or non-metal oxide layers are adhered to one or two surfaces of the polyester film or the fluoropolymer film.

11. A method as claimed in claim 10, wherein the one or two main surfaces of the polyester film or the fluoropolymer film have one or more oxide layers adhered thereto, the oxide layers selected from a group of silicon oxide layers having the general molecular formula SiOₓ, X=1-2 and aluminum oxide layers having the general molecular formula AlOₓ, x=0.5-1.5.

12. A method as claimed in claim 10, wherein the one or two main surfaces of the polyester film or the fluoropolymer film are laminated with one or more metallic layers selected from a group consisting of silver foil, aluminum foil, tin foil and copper foil.

13. The method of claim 1 further comprising the steps of:
(e) providing a second copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the second ethylene copolymer accounts for 60-90% by weight; and
(f) extruding an adhesive layer comprised of at least 70% by weight of the ethylene copolymer of step (e), based on the weight of the adhesive layer, at a temperature of 270° C. or higher on an exposed surface of the stretched polyester film of the fluoropolymer/ethylene copolymer/stretched polyester multilayer laminated film of step (d).

14. A multilayer laminated film comprising a fluoropolymer layer/ethylene copolymer layer/stretched polyester layer, wherein the laminated film is made according to the method of claim 1.

15. A solar panel comprising a front sheet, an electronic circuit and a back sheet, wherein the back sheet comprises the multilayer laminated film of claim 14.

16. A back sheet for a solar panel, comprising:
(a) fluoropolymer film;
(b) a stretched polyester film;
(c) an extruded adhesive layer between said fluoropolymer film and said stretched polyester film, said extruded adhesive layer comprised of at least 70% by weight of copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight.

17. The solar panel back sheet of claim 16, further comprising a second extruded adhesive layer on the surface of the stretched polyester film that is opposite of the fluoropolymer film, said second extruded adhesive layer comprised of at least 70% by weight of copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight.

18. The solar panel back sheet of claim 17, further comprising a second fluoropolymer film adhered to the second extruded adhesive layer.

19. The solar panel back sheet of claim 17, further comprising a metal foil adhered to the second extrude adhesive layer, and further comprising further comprising a third extruded adhesive layer on the surface of the metal foil that is opposite of the stretched polyester film, said third extruded adhesive layer comprised of at least 70% by weight of copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight.

20. The solar panel back sheet of claim 16, wherein a metal foil is disposed between said fluoropolymer film and said stretched polyester film, and wherein said extruded adhesive layer is a first extruded adhesive layer disposed between said fluoropolymer film and metal foil and adhering said fluoropolymer film to a side of the metal foil facing said fluoropolymer film, and further comprising a second extruded adhesive layer disposed between said stretched polyester film and said metal foil and adhering said stretched polyester film to a side of the metal foil facing said stretched polyester film, wherein said second extruded adhesive layer is comprised of at least 70% by weight of copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight.

21. The solar panel back sheet of claim 20, further comprising an exterior extruded adhesive layer on the surface of the stretched polyester film that is opposite of the fluoropolymer film, said exterior extruded adhesive layer comprised of at least 70% by weight of copolymer of ethylene and one or more monomers selected from the group of consisting of C₁₋₄ alkyl acrylates, C₁₋₄ alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer accounts for 60-90% by weight.
